(19) United States
(12) Patent Application Publication
(10) Pub. No.: US 2025/0236508 A1
(43) Pub. Date: Jul. 24, 2025

(54) HIGH-Q MICROMECHANICAL TORSION RESONATOR BASED ON SUSPENDING A TEST MASS FROM A NANORIBBON

(71) Applicants: GOVERNMENT OF THE UNITED STATES OF AMERICA, as represented by THE SECRETARY OF COMMERCE NATIONAL, Gaithersburg, MD (US); ARIZONA BOARD OF REGENTS ON BEHALF OF THE UNIVERSITY OF ARIZONA, Tucson, AZ (US)

(72) Inventors: Jon Robert Pratt, Gaithersburg, MD (US); Stephan Schlamminger, Gaithersburg, MD (US); Aman Rajendra Agrawal, Tucson, AZ (US); Dalziel Joseph Wilson, Tucson, AZ (US)

(21) Appl. No.: 18/703,630

(22) PCT Filed: Oct. 24, 2022
(86) PCT No.: PCT/US2022/078605

§ 371 Date: Apr. 22, 2024

(51) Int. Cl. B81B 3/00; G01L 1/04; G01P 15/093

(52) U.S. Cl. CPC B81B 3/0029; G01L 1/048; G01P 15/093; B81B 2201/0235; B81B 2201/042; B81B 2203/0154; B81B 2203/056

(57) ABSTRACT

The present invention features a micrometer-scale torsion balance device comprising a rigid mass and two or more nanoribbons attached to the rigid mass. The rigid mass may be suspended by the two or more nanoribbons. The two or more nanoribbons may be placed under tensile stress. A local acceleration value may be derived from a torsional stiffness of the two or more nanoribbons. In some embodiments, the rigid mass may comprise silicon. In some embodiments, the two or more nanoribbons may comprise silicon nitride. In some embodiments, the rigid mass may have a polygon shape, the polygon shape having four or more sides. A side of the four or more sides may be longer than all others.

### CROSS-REFERENCES TO RELATED APPLICATIONS

This application claims benefit of U.S. Provisional Application No. 63/270,835 filed Oct. 22, 2021, the specification of which is incorporated herein in its entirety by reference.

### STATEMENT REGARDING FEDERALLY SPONSORED RESEARCH OR DEVELOPMENT

This invention was made with government support under Grant No. 1945832 awarded by National Science Foundation. The government has certain rights in the invention.

### FIELD OF THE INVENTION

The present invention is directed to micrometer-scale torsion balance devices for gravity and local acceleration measurements.

### BACKGROUND OF THE INVENTION

Recent years have seen the emergence of a new class of ultra-high-Q nanomechanical resonators fashioned from strained thin films. The mechanism behind their performance is dissipation dilution, an effect whereby an elastic body is subjected to a conservative stress field, increasing its stiffness without adding loss. Access to extreme dimensions and stresses at the nanoscale has enabled dilution factors (the ratio of final to initial Q) in excess of 10⁵, yielding Q factors in excess of 10⁹ for devices made of amorphous glass and Q-frequency products exceeding 10¹⁵ Hz using “soft-clamping”. Attractive features of these devices include attonewton force sensitivities, thermal coherence times of milliseconds, and zero-point displacement amplitudes in excess of picometers, spurring proposals from room temperature quantum experiments to ultra-fast force microscopy.

Despite rapid innovation, a key limitation of dissipation dilution is its restriction to transverse flexural modes, a consequence of its reliance on nonlinear stress-strain coupling. It has been formally shown that breathing modes, such as the longitudinal modes of a cylinder, cannot be diluted by a uniform strain field, ruling out the application of dissipation dilution to a large class of metrologically important mechanical devices, such as the mirrors used in precision optical cavities and gravitational wave interferometers. It is also commonly held that torsional modes of nanostructures are not diluted by strain, despite the prevalence of tensioned micro suspensions in macroscopic torsion pendula and the historical use of micro-torsion resonators to study mechanical dissipation.

### BRIEF SUMMARY OF THE INVENTION

It is an objective of the present invention to provide devices that allow for micrometer-scale torsion balance devices for gravity and local acceleration measurements, as specified in the independent claims. Embodiments of the invention are given in the dependent claims. Embodiments of the present invention can be freely combined with each other if they are not mutually exclusive.

Here, it is shown that torsional resonators can experience massive dissipation dilution due to nanoscale strain, and draw a connection to a century-old theory from the torsion balance community which suggests that a simple torsion ribbon is naturally soft-clamped. By disrupting a commonly held belief in the nanomechanics community, these findings invite a rethinking of strategies towards quantum experiments and precision measurement with nanomechanical resonators. For example, the optical lever technique for monitoring displacement is observed, and it is found that the rotation of a strained nanobeam can be resolved with an imprecision smaller than the zero-point motion of its fundamental torsional mode, without the use of a cavity or interferometric stability. It was also found that a strained torsion ribbon can be mass-loaded without changing its Q factor. This strategy was used to engineer a chip-scale torsion balance whose resonance frequency is sensitive to micro-g fluctuations of the local gravitational field. Enabling both these advances is the fabrication of high-stress Si₃N₄ nanobeams with width-to-thickness ratios of 10⁴ and the recognition that their torsional modes have Q factors scaling as their width-to-thickness ratio squared, yielding Q factors as high as 10⁸ and Q×frequency products as high as 10¹³ Hz.

A millimeter-scale optomechanical torsion resonator includes tensioned SiN tethers that are a torsion suspension for a balance beam. The balance beam can be configured as a torsion spring balance, null force balance, or pendulum resonator; the functionality can be tailored using the balance beam geometry, electrostatic, magnetostatic, electromagnetic, optomechanical, or gravitational force interactions, the location of the beam center of gravity, and the orientation of the frame with respect to gravity, along with many other force interactions. The optomechanical torsion resonator can be used for relative gravimetry, inertial sensing, mass detection, optical power measurement, and the like.

The torsion resonator performs as a torsion balance. The optomechanical torsion resonator can be a force sensor or accelerometer and can be made at chip scale. Flexibility of nanofabrication of the optomechanical torsion resonator so sensors can be made with the resonator geometry of the optomechanical torsion resonator that are integrated so that motion of the optomechanical torsion resonator can be detected using an optical or electrical readout. The optomechanical torsion resonator has a novel dissipation dilution mechanism compared with conventional microfabricated structures. The optomechanical torsion resonator has a Q factor approaching 10⁷. This is unprecedented in this size and form factor. With this high Q, the optomechanical torsion resonator provides high sensitivity. The optomechanical torsion resonator can be tailored by modifying the balance beam or nanoribbon suspension to have a selective change in bandwidth and sensitivity to various external forces or to distribute mass to enhance the inertial response. Further, the balance beam and nanoribbon suspension can be fabricated monolithically using nanofabrication that is compatible with CMOS.

The optomechanical torsion resonator has a compact geometry capable of Q factors that are higher than conventional geometries. The simplicity and manufacturability of the optomechanical torsion resonator are superior to conventional chip scale concepts for relative gravimetry.

It is contemplated that the optomechanical torsion resonator can track changes in local gravity by monitoring the resonance frequency of the optomechanical torsion resonator for a class of sensors used in geospatial mapping and resource discovery. The optomechanical torsion resonator can be highly sensitive to orientation with respect to gravity for use in inertial measurement units for autonomous vehicles.

One of the unique and inventive technical features of the present invention is the derivation of local acceleration from torsion of nanoribbons under tensile stress. Without wishing to limit the invention to any theory or mechanisms, it is believed that the technical feature of the present invention advantageously provides for high-Q and accurate measurement of gravity forces and local acceleration, among other parameters. None of the presently known prior references or work has the unique inventive technical feature of the present invention.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCRIPTION OF THE SEVERAL VIEWS OF THE DRAWING(S)

The features and advantages of the present invention will become apparent from a consideration of the following detailed description presented in connection with the accompanying drawings in which:

FIG. 1A shows an embodiment of the torsion balance device of the present invention.

FIG. 1B shows an alternate embodiment of the torsion balance device of the present invention with a plurality of nanoribbons in-plane with each other.

FIG. 2 shows a sample embodiment of the torsion balance device of the present invention as well as a lumped parameter model of the present invention.

FIG. 3A shows an embodiment of the rigid mass of the present invention.

FIG. 3B shows a top-down view of the rigid mass of the present invention suspended by two nanoribbons.

FIGS. 4A-4H show a fabrication process of the rigid mass of the presently claimed invention.

FIG. 5 shows a torsion pendulum formed by suspending a rigid mass m from beam-like torsion fiber. The gravity loads the fiber into tension T=mg. A beam of width w and thickness h loaded under tensile stress σ=T/wh. Bifilar model of torsion mode: transverse displacement u preserves the beam length L to first order, leading to dissipation dilution.

FIG. 6 shows a schematic of the optical lever technique: A Gaussian beam with a waist of w₀ is reflected off of a torsion beam of width w. Beam deflection θ is monitored using a split photodiode.

FIG. 7 shows finite element models of torsion modes for a nanobeam without mass loading.

FIG. 8 shows photos of representative devices: (top) a 400 um wide, 7 mm long, 75 nm thick beam; (middle) a 25 um wide, 7 mm long, 75 nm thick beam loaded with a 100 μm thick Si paddle; and (bottom) a micrograph of the paddle.

FIG. 9 shows displacement of a w=400 μm beam measured using a w₀≈200 μm, P=4 mW optical lever.

FIGS. 10A-10D are directed to a microtorsion pendulum for weak gravity measurement.

FIG. 10A shows geometry of the torsion pendulum, produced by mass-loading a Si₃N₄ nanoribbon with a rigid Si pad.

FIG. 10B shows photographs of the device in non-inverted and inverted configuration.

FIG. 10C shows a free-running deflection spectrum of the pendulum in non-inverted and inverted configuration.

FIG. 10D shows ringdowns of the fundamental torsional mode in non-inverted and inverted configuration.

### DETAILED DESCRIPTION OF THE INVENTION

Following is a list of elements corresponding to a particular element referred to herein:
100 device
110 rigid mass
120 nanoribbon

The present invention features a micrometer-scale torsion balance device (100) comprising a rigid mass (110) and two or more nanoribbons (120) attached to the rigid mass (110). The rigid mass (110) may be suspended by the two or more nanoribbons. The two or more nanoribbons (120) may be placed under tensile stress. A local acceleration value may be derived from a torsional stiffness of the two or more nanoribbons (120). In some embodiments, the torsional stiffness is used to derive static or resonant motion of the mass, and the torsional stiffness is observed optomechnically, electromechanically, etc. In some embodiments, the rigid mass (110) may comprise silicon. In some embodiments, the two or more nanoribbons (120) may comprise silicon nitride. In some embodiments, the rigid mass (110) may have a polygon shape, the polygon shape having four or more sides. A side of the four or more sides may be longer than all others. 100 or more megapascals of tensile stress may be applied to the two or more nanoribbons (120). The rigid mass (110) may comprise a mirror surface, and a radiation pressure force can be derived from a movement of the rigid mass (110). The rigid mass (110) may comprise a mirror surface that may be magnetic, and a strength and direction of a magnetic field is derived from a movement of the rigid mass (110).

The present invention features a micrometer-scale torsion balance device (100) comprising one or more nanoribbons (120), wherein the one or more nanoribbons (120) are placed under tensile stress, and wherein a local acceleration value is derived from a torsional stiffness of the one or more nanoribbons (120). The two or more nanoribbons (120) may comprise silicon nitride. In some embodiments, 100 or more megapascals of tensile stress are applied to the two or more nanoribbons (120). The one or more nanoribbons (120) may each comprise an optical waveguide, and amplitude and modulation of light directed through the optical waveguide can be derived from a torsional deformation of the two or more nanoribbons (120).

The present invention features a micrometer-scale torsion balance device (100) comprising a rigid mass (110) having a polygon shape. The polygon shape may have four or more sides, and a side of the four or more sides may be longer than all others. The device (100) may further comprise four or more nanoribbons (120) attached to the rigid mass (110) such that the four or more nanoribbons (120) are in-plane with each other. The rigid mass (110) may be suspended by the four or more nanoribbons (120). The four or more nanoribbons (120) may be placed under tensile stress, and a local acceleration value may be derived from a torsional stiffness of the four or more nanoribbons (120).

In some embodiments, the rigid mass (110) comprises silicon. In some embodiments, the four or more nanoribbons (120) comprise silicon nitride. 100 or more megapascals of tensile stress may be applied to the four or more nanoribbons (120). The four or more nanoribbons (120) may be parallel to each other. The rigid mass (110) comprises a mirror surface, and a radiation pressure force can be derived from a movement of the rigid mass (110). The rigid mass (110) may comprise a magnetic mirror surface, and strength and direction of a magnetic field is derived from the movement of the rigid mass (110).

In some embodiments, the resonant frequency of the device (100) is 10 Hz to 1 kHz. In some embodiments, the Q range of the device (100) is at least 10,000 and at most 10⁹. The multiple nanoribbons suspending the rigid mass may act as a hinge for the rigid mass, allowing it to rotate instead of sagging/swinging. In some embodiments, the dimensions of the ribbon may be tailored such that vibrations as a result of torsion are localized at certain points.

### Example

The following is a non-limiting example of the present invention. It is to be understood that said example is not intended to limit the present invention in any way. Equivalents or substitutes are within the scope of the present invention.

The starting point for this device is the realization that high-stress Si3N4 nanoribbons possess torsion modes with anomalously high Q factors. The physical mechanism behind this behavior is dissipation dilution, an effect whereby a thin ribbon placed under tensile stress experiences increased torsional stiffness without added loss. This gives rise to a simple scaling law for the quality (Q) factor of a ribbon proportional to its width w to thickness h ratio squared

$$\frac{Q}{{Q}_{0}} = 1 + \frac{{k}_{σ}}{{k}_{E}} \approx \frac{σ}{2 E} {( \frac{w}{h} )}^{2} \qquad ( 1 )$$

where Q₀ is the intrinsic (unstressed) quality factor of the torsion mode, k is the torsional stiffness due to tensile stress, and k_{E} is the torsional stiffness due elastic modulus E.

The validity of Eq.1 was tested for a range of ribbon widths spanning 10-400 μm. For ribbons with w=400 m, h=75 nm, torsion modes with Q˜10⁸ and resonance frequencies of ˜50 kHz were observed, on par with state-of-the-art membrane resonators with similar dimensions.

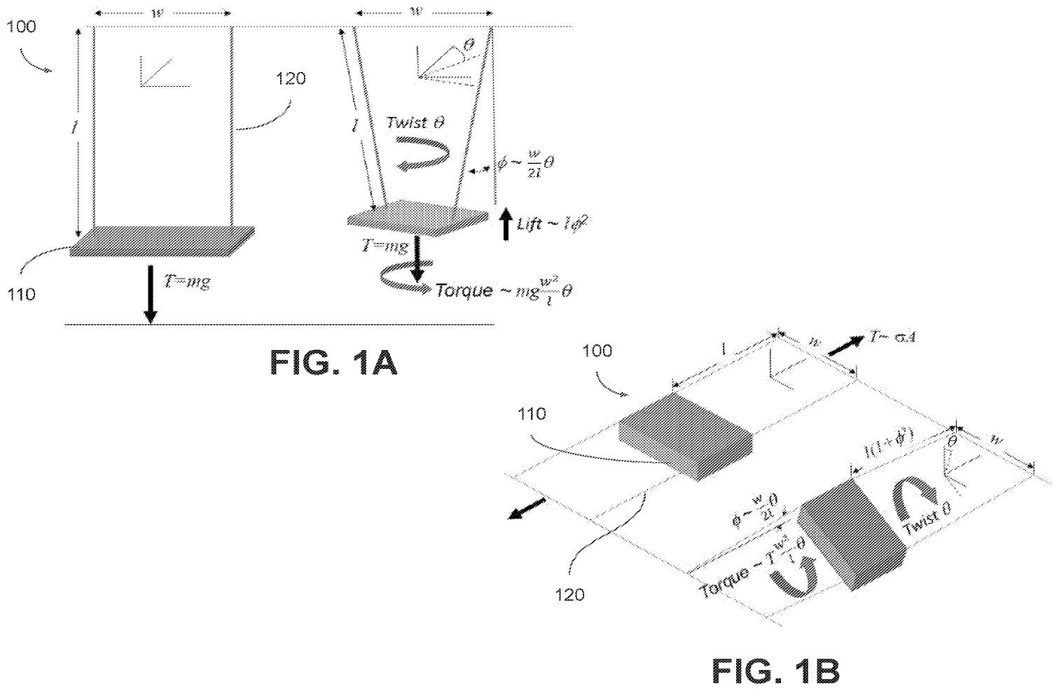

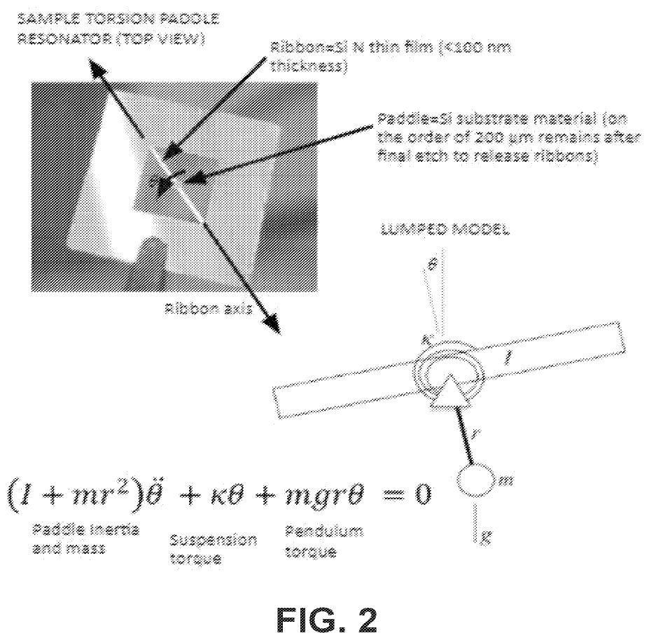

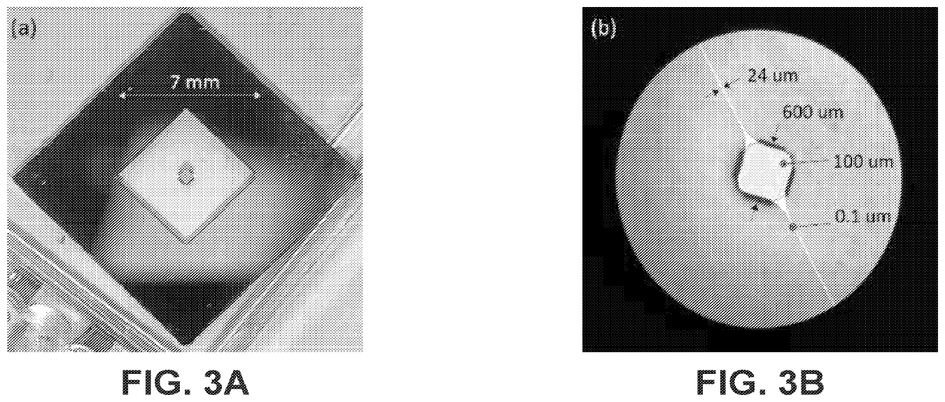

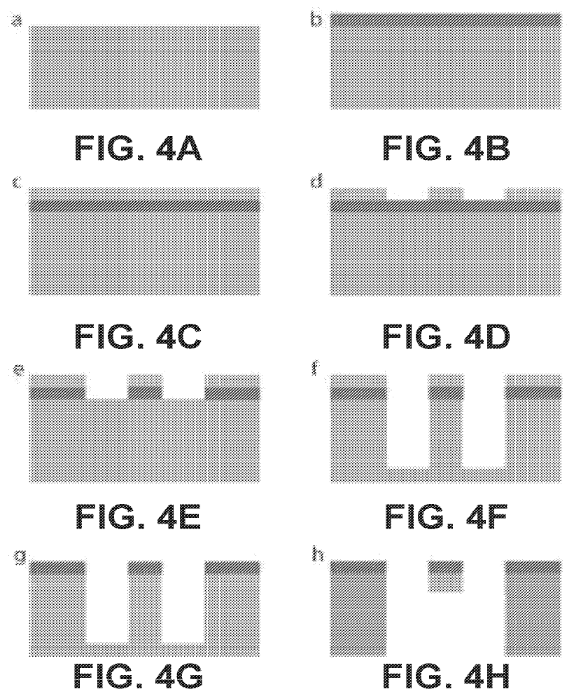

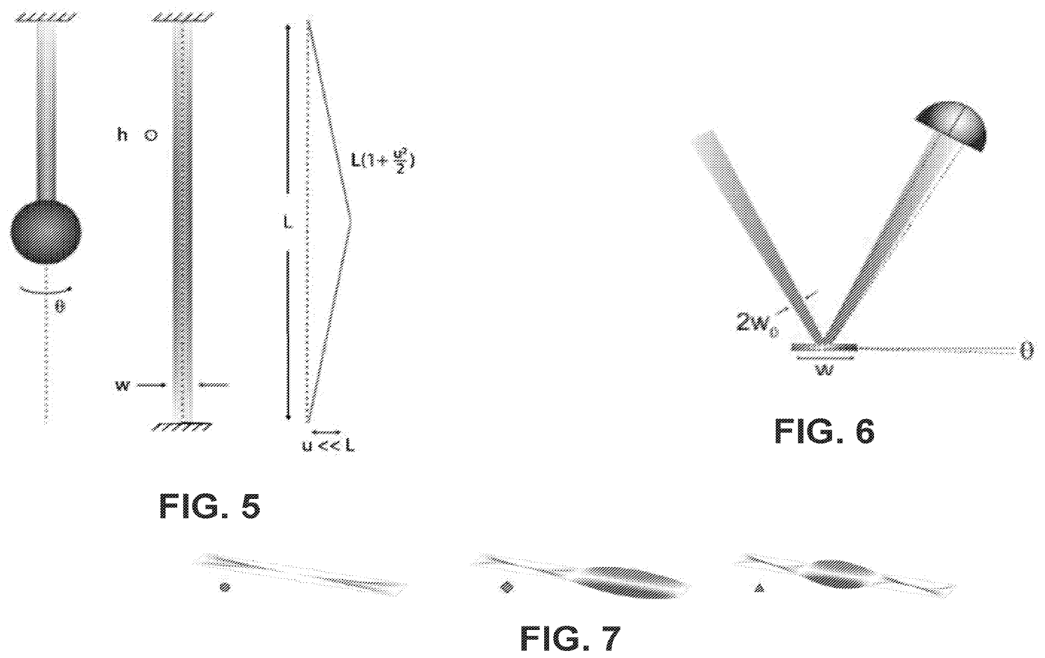

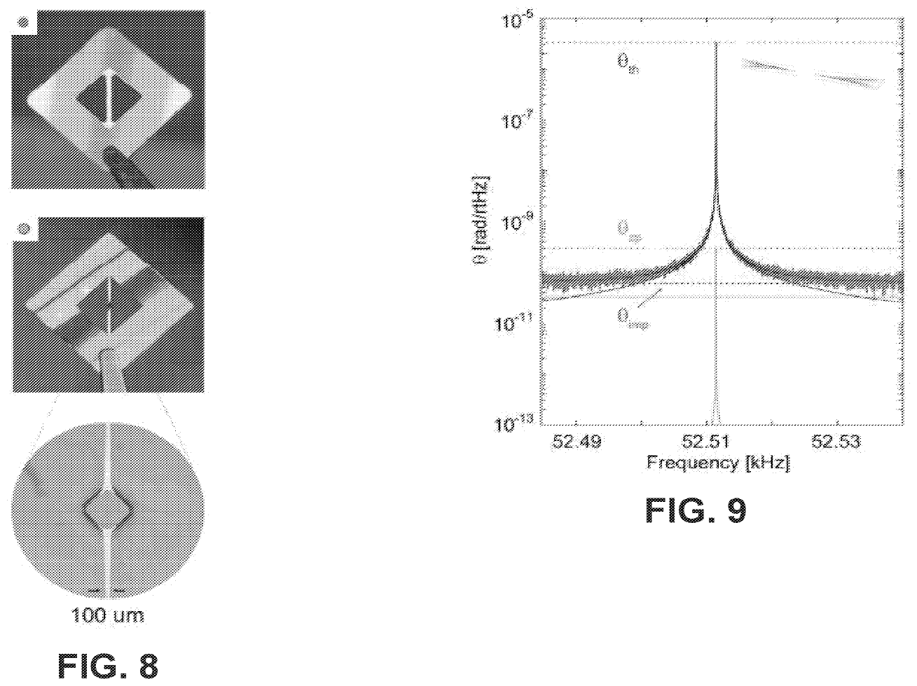

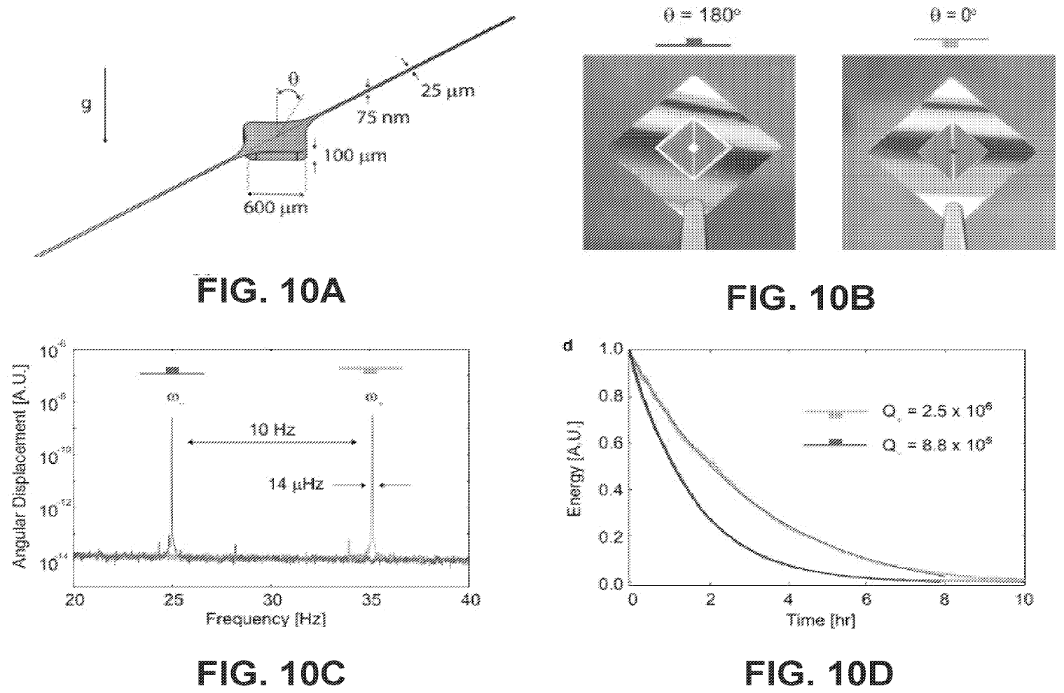

The genesis of torsion microbalance is the finding that (remarkably) mass-loading a Si3N4 nanoribbon does not reduce its Q. A L=7 mm long, w=25 μm wide nanoribbon is loaded with a 600 μm wide, 100 m thick torsion paddle (FIG. 1b). The concomitant 10⁶-fold increase in moment of inertia results in a drop of the fundamental torsion mode frequency from f=50 kHz to f=35 Hz. Despite this large reduction in frequency, a quality factor Q≈2.5×10⁶ was observed, corresponding to a ˜10 hour ringdown time (FIG. 1c), or a damping rate of 14 μHz. It is confirmed that torsion balances with different ribbon suspension widths follow the same scaling law as the unloaded ribbons, yielding Q-m products on the order of a kilogram, corresponding to thermal noise equivalent angular acceleration of \sqrt{8πk_{B}Tf/mQ}˜1 μrad/s²/\sqrt{Hz}. As outlined in the next section, the torsion microbalance is also a highly sensitive parametric gravity transducer, with micro-g changes in local gravity producing a frequency shift on the order of the mechanical damping rate.

Owing to its asymmetric loading, the chip-scale torsion balance is in fact a torsion pendulum, whose frequency depends on gravity through its gravitational stiffness

$${k}_{g} = \frac{1}{2} mg H ,$$

where H is the paddle thickness. The ratio of k_{g} and the torsional stiffness k is roughly 1:2; as such, flipping the device results in a frequency shift of f=10 Hz, which is a significant fraction of the original, non-inverted frequency, f₀=35 Hz. Comparing to the mechanical linewidth f₀/Q≈14 μHz, it is inferred that a damping-equivalent gravity resolution (g) of

$$\frac{Δ g}{{g}_{0}} ∼ \frac{1}{Q} \frac{{f}_{0}}{Δ f} ∼ {10}^{- 6} \qquad ( 2 )$$

Where g₀≈9.8 m/s2 is the standard acceleration due to gravity on Earth's surface.

To meet the demands of the next-generation Kibble Balance, a benchmark relative precision to local gravitational fluctuations on the order of 10⁻⁸ is required when the sensor output is averaged over periods less than 1000 seconds. This implies that the resonance frequency of torsion microbalance must be resolved with a precision 1000 times smaller than its linewidth (the mechanical damping rate). Towards this end, a series of measurements explored the Allan Deviation of the frequency of the torsion micropendulum, in an effort to identify sources of both external and self-noise.

The resonance frequency was recorded for several hours and computed the fractional Allan deviation σ_{f}(τ), as a function of record length (measurement time). The inferred resolution to gravity, expressed also as a fractional Allan deviation, is given by

$${σ}_{g} ( τ ) \approx \frac{{f}_{0}}{Δ f} {σ}_{f} ( τ ) \qquad ( 3 )$$

and is plotted on the right-hand axis. Three variations are shown. For the green curve, the free-running motion of the torsion pendulum driven by thermal noise and ambient seismic noise was monitored (the device is mounted in an ultra-high-vacuum chamber atop an optical table and a secondary pendulum vibration isolation system with a corner frequency of 1 Hz, to minimize the latter), and compare it with a thermal noise model given by

$${σ}_{f} ( τ ) = \sqrt{\frac{{τ}^{- 1}}{2 {ω}_{0} Q}} . \qquad ( 4 )$$

An ultra-sensitive torsional balance is based on silicon nitride membrane technology. The torsion device, shown below, includes a 100 μm test mass suspended from two silicon nitride nanoribbons, forming a chip-scale ˜10 Hz torsional balance. Stress-induced dissipation dilution results in a quality factor of Q≈10⁶ for the balance, yielding an unprecedented (for this form factor) thermal acceleration sensitivity of

$${a}_{th} \approx 1 {0}^{- 9} {g}_{0} / \sqrt{Hz} .$$

This membrane platform can provide an array of sensors for single photon force detection.

The authors have developed two methods of fabricating a micromechanical torsion pendulum that differ in the way that the resonators are etched following the photolithography process. The former method, developed at the University of Arizona, relies on a wet chemical process employing potassium hydroxide (KOH) as a selective etchant to remove the silicon from underneath the Si₃N₄ film. The presentation implements the additional step of patterning a window on the back side of each wafer to reduce overall etch time. Following the etch, wet solvents are used to clean the surface of the film prior to characterization.

Parallel to the efforts at the University of Arizona (UA), an entirely dry wafer-scale approach is under development at the National Institute of Standards and Technology in Gaithersburg, MD (NIST-G). The process flow is enabled by plasma deep reactive ion etching (DRIE) and gas phase Xenon Difluoride (XeF2) etching methods. The use of these techniques, in contrast to the wet chemical methods used at UA, eliminates the need for back-side wafer patterning since the devices can be undercut and released from trenches formed around the sample.

Another side effect of mass-loading a tensioned nanoribbon is the high degree of angular rotation experienced by the test mass about its torsion axis when it is either actively driven by a feedback system or passively driven by ambient seismic activity. The amplitude of the resulting angular deflections presents a challenge for stable interferometric readout, and a different approach is required to extract a useful signal. Toward this end, the optical lever technique was used to make continuous measurements of pendulum motion for sufficiently small deflection amplitudes, a limit that is ultimately imposed by the aperture of the detector.

To analyze a continuous optical lever deflection signal, the analog output of a split photo-diode is converted into a digital signal by a 24-bit digitizer module. A fast Fourier transform (FFT) of the signal is computed to determine the pendulum's resonance frequency, and a time interval analyzer (TIA) is used to monitor the frequency stability to characterize its performance as a clock. In the continuous measurement case, the TIA is a template-matching algorithm deployed in-situ by data acquisition software. Further spectral analysis is conducted to study potential sources of noise in the system and to locate additional modes of vibration (such as the transverse flexural modes).

A novel micromechanical torsion balance includes tensioned SiN nanoribbons to suspend a rigid silicon balance beam. The high tensile stress that can be achieved in SiN nanoribbons is exploited here to create a nearly lossless torsional constant that dilutes the effects of elastic deformation and yields Q factors over 1×10⁶ for the 10's of Hz fundamental torsional mode of these 0.1 mg prototype devices. A simple theory was used that explains the relative contributions of elastic, tensile, and gravitational torques to the total torsional spring constant, appealing to well-known results from macroscopic torsion balances. From the relative contributions of these spring constants, a dilution relationship was deduced based on the magnitude of tensile force and the geometric cross-section of the ribbon suspension. This theory successfully predicts the magnitude of Q enhancement witnessed in these experiments assuming only that the well-documented real and imaginary (anelastic) components of elastic bending deformation observed previously in SiN membranes yield similar behavior for twisting in shear. The result is surprising, given the conventional wisdom that dilution cannot be achieved using membrane stress in nanomechanical torsion devices. The ultra-high-Q micromechanical balance is compatible with existing nanofabrication processes, lends itself to easy integration with on-chip light sources, waveguides, and/or patterned electrodes for detection and/or actuation schemes, can be fabricated singly or in arrays, and creates a revolutionary new platform for the quantum-limited detection of forces below a piconewton.

The torsion balance first employed by Coulomb to observe the inverse square law that bears his name is the most successful scheme yet for measuring gravity and other weak forces. Recent efforts have focused on shrinking the physical dimensions and coupling the mechanics to optical cavities for readout and to modify the underlying dynamics. The aim is to achieve ever higher sensitivity from the devices while minimizing sources of intrinsic noise. Here, a novel approach was demonstrated to dilute the losses in a micromechanical torsion balance by appealing to the bifilar effect first described by Buckley in 1914.

A pendulum or balance beam in thermal equilibrium at temperature T experiences a thermal torque at frequency ω dependent on the Boltzmann constant k_{b} and characterized by the spectral density (C. W. McCombie, Rep. Prog. Physics 16 266 (1953))

$${S}_{τ}^{th} ( ω ) = 4 {k}_{b} TI {γ}_{m} ( ω ) ,$$

where I is the moment of inertia of the pendulum bob or balance beam about the pivot axis and gm(w) the mechanical loss of the suspension. Thermal torques are the limiting factor in most weak force measurements using torsion devices. Clearly, there is motivation to reduce both the size and the mechanical loss in order to minimize this noise. Suspension loss typically increases as the dimensions shrink when the mechanical spring effect is due to bending or twisting of the cross-section since surface defects dominate at small cross-sections. This has led to strategies at the macroscale that dilute the influence of the suspension via gravitational spring (Quinn Big G) effects and more recently at the microscale via optical spring effects.

The local acceleration of gravity g acts on the balance beam center of gravity with force mg offset from the pivot a fixed distance r and at angle φ producing a gravitational torque τ_{g}=mgr cos cos (θ−ϕ) that rotates the balance beam as gravity changes. Such a balance is a mechanical spring-mass oscillator with torsional spring constant k (potentially complex in the case of structural damping) and viscous damping coefficient β that executes simple harmonic motion described by

$$I \ddot{θ} + β \dot{θ} + κθ = {τ}_{g} ,$$

where I is the mass moment of inertia. The gravitational torque at a fixed location on earth typically varies only slowly with time, and the DC response of a torsion balance can be employed as a relative gravimeter

$$κθ = {τ}_{g} ,$$

so that the balance sensitivity is characterized by 1/k and the challenge for gravimetry is to resolve the static torque to within a few parts in 10⁹, the present state of the art.

Focusing for the moment on the spring, the highest sensitivity torsion balance is obtained by driving k to zero, thereby creating a constrained but freely falling mass with infinite sensitivity; unfortunately, the infinite rotation due to the static torque quickly becomes impractically large, and this scheme is usually accompanied by some sort of feedback force to restore the displacement to null.

The classic torsion fiber is a wire of circular cross-section that provides a restoring torque proportional to the shear modulus times the radius to the fourth power. As noted by Speake and Quinn, such fibers are prone to anelastic behavior that limits the Q. This observation led them to choose a ribbon for the construction of the balance employed in their Newtonian gravitational experiment, because the restoring torque of a ribbon is dominated by the tensile gravitational force acting on the suspended mass. A restoring torque arises in twisted strips under tension because of a bifilar property modeled first by Buckley, Philosophical Magazine, 1914. For a strip of length l, width b, and thickness t, under a tensile load T, the bifilar property gives rise to a restoring couple per unit angular displacement

$${c}_{T} = \frac{{Tb}^{2}}{12 l} ,$$

while to first approximation the torsion constant of a strip of material having shear modulus G at zero loads is,

$${c}_{0} = \frac{{bt}^{3}}{3 l} G ,$$

and the total torsional spring constant is simply k=c_{T}+c₀.

The restoring couple c₇ depends only on tension in the strip, while the torsion constant c₀ depends on the elastic deformation of the material. The former should be nearly lossless, while the latter is anticipated to be bound by anelastic losses.

The argument for the lossless character of the tensile restoring force is elementary but worth reviewing. Consider a perfect string of length L, held under tension, T, clamped at z=0 and z=L, displaced vertically from equilibrium at z=L/2 by a distance x=d. A perfect string experiences no bending at the boundaries, so the deflected shape of the string is simply a triangle of height d and base L. The angle the string makes with respect to horizontal at each end is θ=tan⁻¹ (2 d/L). The force that resists this deflection is the sum of the opposing components of the tension, F=2T sin θ+2dT. The term dT can produce anelastic loss only if the deflection causes a stretching of the string. But for small angles, the term disappears to first order. Thus, large tensile stress induces a bias that is effectively constant compared to any perturbative stretching of the membrane midplane. The stress will depend on temperature, although the effect is weak and comparable to the coefficient of thermal expansion for the material. Buckley goes on to consider an infinite set of parallel fibers deflected along a line twisting in space and arrives at the expression for c_{T} above.

It is assumed that the shear modulus has both real and imaginary components, G=G+i_{G}, where the imaginary component captures the anelastic behavior of the material. It is further assumed that the amount of elastic strain energy partitioned to the anelastic behavior will be in the same proportion as for transverse bending of a thin plate about its neutral axis, where it is now generally accepted that the elastic loss places an upper, intrinsic bound on the resonator quality factor Qᵢₙ of 5000 for nanomechanical structures composed of thin films of stoichiometric SiN. An intrinsic Q factor is dependent on a thickness of the film. For example, for a 75 nm thick SiN film, the intrinsic Q values is 4500. From here, it is argued that conditions resulting in c_{T}>>c0 should lead to higher values of Q since the potential energy of the ribbon is increasingly dominated by the lossless factor.

Certainly, this has been the case for transverse modes of tensioned Si N membranes, where impressive boosts in Q factor with increasing stress have become the norm. No such similar behavior has been reported yet for tensioned Si N tethers in torsion, so it must be considered if the condition cT>>c0 can be achieved in such systems for the magnitudes of residual stress that are routine in Si N nanofabrication processes.

First, the ratio of restoring couples was expressed as

$$\frac{{c}_{T}}{{c}_{0}} = \frac{b}{4 {t}^{3}} \frac{T}{G}$$

The load T was expressed as the product of the membrane tensile stress s_{T} and the cross-sectional area b. substitute typical values of stress and modulus, and find

$$\frac{{c}_{T}}{{c}_{0}} = \frac{1}{4} {( \frac{b}{t} )}^{2} \frac{{σ}_{T}}{G} = \frac{1}{4} {( \frac{b}{t} )}^{2} \frac{\text{∼1} GPa}{\text{∼145} GPa}$$

Evidently, a torsion strip with b/t>24 begins to be dominated by tension versus torsion effects. A review of the scant available torsion literature reveals that this parameter space has been ignored thus far.

A highly stressed thin film of Si N with t=100 nm is perhaps as thin as can be reliably fabricated at present. c_{T} must be at least 10×c₀, so b=8 μm, at a minimum.

The simplest balance structure to consider is the inertia bar supported by a pair of strips. The torsion spring constant k of this system is anticipated to be 2 c_{T}, within ten percent. Plugging in the nominal values for b, t, and s_{T},

$$κ \approx \frac{{σ}_{T} {b}^{3} t}{6 l} \approx \frac{1 Gpa {( 8 µm )}^{3} 100 nm}{6 l} \approx \frac{5 {( 10 )}^{- 14} {Nm}^{2}}{l}$$

So that tethers with 1=5×10⁻² m would yield a nominal torsion constant of 1 pN m. Recall that the desired inertia beam would have e.g. offset from the pivot to produce a torque of approximately 1 pN m, so that the equilibrium deflection would be on the order of 1 rad, readily detectable to parts in 10⁷ using an optical lever, perhaps better.

In order to exploit optical force effects, the optical power must be increased and/or consider a long inertia beam (>0.3 m). Considering both, it was found that 30 mW and L=10 mm create a torque of 1 pN m.

All torques are equal. Levitation is possible using only optical forces. No mechanical spring. No electrostatics. Alternatively, the torsional stiffness can be effectively doubled using the optical force.

If necessary, the light can be amplified using multiple passes, as in Komori, et al 2020, where they achieved 10 W circulating power for an order 10 mW incident light. Assuming similar results, then in principle, the optical force effects could be increased to 6 nN×L, so that L on the order of 10⁻³ m would be adequate to explore canceling the gravitational torque and to either increase or decrease the stiffness with a lossless spring.

While experimentally challenging, dilution via tension, gravity, and optical spring effects are all viable using the present state of the art. However, it appears that dilution via tension in the suspension has yet to be considered in the literature, outside these investigations.

There are multiple ways to create pendulums from this simple geometry. Orienting the frame vertically is perhaps the most obvious. Even here, it is interesting to consider an inverted geometry, since this creates the opportunity to bring optical, suspension, and gravitational effects to the same order, simply by manipulating the offset r.

A set of high-stress Si₃N₄ nanobeams was fabricated with aspect ratios varying from w/h˜10²-10⁴. Devices were housed in a high vacuum chamber to minimize gas damping and ringdowns were performed using optical lever measurements in conjunction with radiation pressure driving. Ringdown-inferred Q factors were then compiled for flexural and torsional modes up to the third order.

Considering first the hypothesis that Q˜(w/h)², Q factors of beams with widths from 10 μm to 400 μm were compared to Eq. 1 and a finite element simulation accounting for fileting. For both models it is assumed σ=0.85 GPa, E=250 GPa, h=75 nm, and Q₀=6000×h/(100 nm) (an established surface loss model for Si₃N₄ thin film resonators). The quantitative agreement was observed with both models up to a width of 100 μm, beyond which Q begins to drop, consistent with simulated buckling instabilities and residual gas damping at the level of Q_{gas}≈10⁹ (dotted line). At widths smaller than 100 μm, a slightly higher Q was observed than predicted. It is conjectured that this may be due to an underestimate of Q₀, since the surface loss model is inferred from a study of flexural rather than torsional modes.

Further support for Eq. 1 was obtained by inspecting higher-order modes and by varying the thickness of several resonators. The continuum model derived in the appendix predicts that Qₙ/Q₀ is independent of mode order n for acoustic wavelengths L/n>>w, in consistency with observations that {Qₙ} is bound by Eq. 1. It was also observed that the fundamental torsional mode had consistently high Q. This is contrary to the typical behavior of flexural modes of Si₃N₄ beams and membranes and suggests that torsional modes may be more resistant to acoustic radiation (“mounting”) loss.

Finally, several beams were fabricated with a thickness 180 nm, and observed that the Q of torsional modes scaled inversely with thickness. By contrast, as shown in the appendix, it was observed that the Q of flexural modes were roughly independent of width and thickness. These different scalings are tell-tale signatures of “soft-clamping” (Q/Q₀∝w²/h²) and “hard-clamping” (Q/Q₀∝w/h), respectively, in the presence of surface loss (Q₀∝h).

Nanomechanical resonators have been probed at the quantum limit using cavity-enhanced interferometry. In principle, however, neither a cavity nor interferometry is necessary, provided that the measurement is optimally efficient. In the study of Si₃N₄ nanobeams, it was found that the imprecision of optical lever measurements S_{θ}^{lmp} (here expressed as a power spectral density) can be reduced to below the zero-point angular displacement of the beam's fundamental torsion mode S_{θ}^{ZP}, satisfying a basic requirement for displacement measurement at the Standard Quantum Limit (S_{θ}^{imp}+S_{θ}^{ba}+S_{θ}^{ZP}, where S_{θ}^{ba} is the displacement produced by back-action torque S_{τ}^{BA}≥ℏ/S_{θ}^{ZP}). This represents the first non-interferometric displacement measurement with an imprecision below that at the Standard Quantum Limit. Combined with robustness to misalignment and technical noise, access to quantum-limited deflection measurements signals the potential for a new generation of quantum optomechanics experiments employing cryogenic or even room temperature nanotorsion resonators coupled to optical levers.

To explore the potential for torsional quantum optomechanics, the optical lever technique was implemented with an eye to maximizing the ratio S_{θ}^{ZP}/S_{θ}^{imp} for a torsion beam. The “lever” is formed by reflecting a laser field off the beam and monitoring its deflection on a split photodiode. In the far-field, angular displacement of the beam θ can be resolved with a shot-noise-limited resolution of

$${S}_{θ}^{imp} ≳ \frac{1}{{w}_{0}^{2}} \frac{ℏ c λ}{8 P}$$

where P is the reflected power and w₀ is the spot size of the laser field. Compared to the zero-point displacement spectral density of the beam's fundamental torsion mode

$${S}_{θ}^{ZP} = \frac{1}{{w}^{2}} \frac{8 ℏ {Q}_{1}}{{m}_{1} {ω}_{1}^{2}} ,$$

(effective mass m₁=ρhwL/6), it was found that maximum “leverage” is achieved by matching the width of the optical and mechanical beams (w₀≈w/2), giving access to a favorable scaling S_{θ}^{ZP}/S_{θ}^{imp}∝Q₀w/h³ due to dissipation dilution.

A powerful feature of nanobeams is their ability to be mass-loaded without reducing their torsional Q factor. The concomitant reduction in resonance frequency and damping rate is useful for a variety of inertial sensing applications. For instance, by asymmetrically loading a beam, a torsion pendulum is created whose resonance frequency depends on the local acceleration of gravity. The gravity-equivalent damping rate of the pendulum gives a measure of its sensitivity as a gravimeter:

$$Δ {g}_{m i n} = \frac{4 {g}_{0}}{{Q}_{+}} \frac{{ω}_{+}^{2}}{{ω}_{+}^{2} - {ω}_{-}^{2}} = \frac{2 {g}_{0}}{{Q}_{0}} \frac{{k}_{E}}{{k}_{g}}$$

where g₀=9.8 m/s² is the standard gravity of the earth and

$$\text{ω±} = \sqrt{( {k}_{E} + {k}_{σ} \pm {k}_{g} ) / I} \\ Q \pm = {Q}_{0} ( 1 + \frac{{k}_{σ} \pm {k}_{g}}{{k}_{E}} ) = Q ∓ {( \frac{\text{ω∓}}{\text{ω±}} )}^{2}$$

are the resonance frequency and Q factor of the pendulum in the inverted (−) and non-inverted (+) configuration.

A passively stable, chip-scale torsion pendulum sensitive to micro-g gravity fluctuations (Δgₘᵢₙ˜g₀/10⁶) by suspending a rigid Si mass from Si₃N₄ nanoribbon has been realized. To understand this advance, it is important to note that the sensitivity of a pendulum gravimeter is independent of tensile stress and is maximized by overwhelming the elastic stiffness of the torsion fiber k_{E} with gravitational stiffness due to mass-loading k₈. Historically, this insight has driven the pursuit of unstressed torsion fibers, culminating most recently in fibers made of 2D materials; however, a limitation of this approach is that the bias point of the torsion fiber becomes unstable for k_{g}>k_{E}, necessitating the use of anti-springs to balance the static load, adding complexity, and mechanical loss. Provided it does not add dissipation, tensioning the torsion fiber restores bias stability as long as k₀+k_{E} ≳k_{g}, giving access to large sensitivity enhancement (k_{g}/k_{E}>>1) for ribbon-like torsion fibers made of a sufficiently strained material that k₀>>k_{E}.

The pendulum was formed by suspending a 100 μm thick, 600×600 μm² wide Si pad beneath a 75 nm thick, 25 μm wide Si₃N₄ beam by under-etching a central defect. In-vacuum measurements revealed a 1000-fold drop in the fundamental torsion resonance frequency of the beam from 40 kHz to 34 Hz, corresponding to a million-fold increase in moment of inertia. Despite this substantial mass-loading, ringdown measurements revealed an increased quality factor of Q₊≈2.5×10⁶ relative to the unloaded beam (Q₀≈1.5×10⁶), consistent with gravitational dissipation dilution with a stiffness hierarchy of k₀≈2k_{g}≈200k_{E}. In principle, the resonance frequency of this pendulum should be sensitive to gravity at the level of Δgₘᵢₙ=2×10⁻⁶g₀.

To explore its potential as a gravimeter, the pendulum was inverted and its resonance frequency and Q factor were remeasured. A 10 Hz drop in resonance frequency (ω₋/ω₊=0.71) and a three-fold drop in Q factor (Q₋/Q₊=0.35) were observed. In practice, the performance of a pendulum gravimeter depends on its frequency stability. These preliminary attempts to track the resonance frequency of the pendulum in its non-inverted configuration yielded a minimum Allan deviation of σ_{δω+}/ω₊≈2×10⁻⁶ at 600 seconds, corresponding to a gravity uncertainty of σ_{δg/g}≈8×10⁻⁶g₀.

Finally, it was noted that similar sensitivity can be obtained with wider, stiffer torsion ribbons possessing higher Q factors. Micro-torsion pendula with ribbon widths varied between 25 and 100 um were investigated. The Q factor and resonance frequency of these devices was found to scale quadratically with width, in agreement with the lumped mass model. For a pendulum based on a 50 μm wide ribbon, a loaded quality factor as high as Q₊≈1.0×10⁷ and an inverted frequency ratio of ω₋/ω₊=0.92 were observed, corresponding to a gravity-equivalent damping rate of Δgₘᵢₙ=3×10⁻⁶g₀.

It has been shown that torsion modes of nanostructures can experience massive dissipation dilution due to thin film stress, paving the way for a new class of ultra-high-Q nanomechanical resonators with applications to quantum experiments and precision measurement. Specifically, high-stress Si₃N₄ nanobeams with width-to-thickness ratios as large as 10⁴ were studied and found that their torsion modes have Q factors that scale as the width-to-thickness ratio squared, yielding Q factors as high as 10⁸. Various features of these resonators spark the imagination. For example, a beam 400 μm wide and 75 nm thick was found to support torsional modes with Q-frequency products exceeding 6×10¹² Hz (a thermal decoherence time exceeding one mechanical period) and its rotation was resolved using an optical lever with an imprecision 20 dB below that at the Standard Quantum Limit, signaling the potential for a new branch of torsional quantum optomechanics. It was also found that strained nanobeams can be mass-loaded without affecting their torsional Q, yielding chip-scale torsion pendula with Q-m factors as high as 0.1 kg and damping rates as low as 10 μHz. It has been shown how such a device might be used to create a chip-scale micro-g gravimeter (competing in size and simplicity with recent MEMS proposals that employ much larger masses and more complex spring geometries). It is also noted that its torque sensitivity, 10⁻¹⁹ Nm/√Hz, is on par with the best that has been achieved with milligram test masses using optical levitation, and as such might be applicable to recent proposals for probing the interface between gravitational and quantum physics. Finally, it was found that measurements indicate that torsion modes of a strained nanobeam are naturally soft-clamped, enabling near-ideal dissipation dilution factors—for both the fundamental and higher order modes—without the need for sophisticated mode-shape engineering techniques such as phononic crystal and fractal patterning. This finding suggests that the landscape for nanoscale dissipation dilution—torsional and otherwise—remains largely unexplored.

Fabrication begins by coating a 1.5 um thick S1813 positive tone photoresist on a double-sided, 100 nm thick Si3N4-on-silicon wafer. The resist on one side of the wafer (the front side) is patterned in the shape of torsion pendulum using a photolithography system (MLA 150), while the resist on the other side protects the wafer from handling scratches. The pattern is transferred to the Si3N4 thin film using fluorine-based (Ar+SF6) reactive ion dry etching. The remaining resist is then removed and a fresh resist layer is applied to protect the front side of the wafer. The backside is then patterned with square windows while making sure it is aligned with the front side\cite. After dry etching the backside pattern, the remaining resist is removed and the wafer is cleaned using oxygen plasma to remove any lingering resist residues. A thick layer of resist is then coated on both sides and the wafer is diced into 12×12 mm\hat{ }2 square chips. The chips are then cleaned using 10 s dip in hydrofluoric acid (HF) followed by a de-ionized (DI) water and isopropanol (IPA) rinse. Chips are then mounted onto a custom polytetrafluoroethylene (PTFE) holder to secure them in a vertical orientation. The assembly is then etched in a potassium hydroxide (KOH) bath at 85 C for 21 hr in order to remove the silicon in the patterned region and subsequently release the pendulum. Due to the large pad size and anisotropic etching of Si along the <100> crystal plane, there remains an approximately 100 μm thick Si mass suspended beneath the pad after wet etching. The released structure is dried using a gradual dilution process which includes iteratively replacing KOH with DI water followed by a 10 min HF dip and then an IPA and methanol rinse.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting essentially of” or “consisting of”, and as such the written description requirement for claiming one or more embodiments of the present invention using the phrase “consisting essentially of” or “consisting of” is met.

The reference numbers recited in the below claims are solely for ease of examination of this patent application, and are exemplary, and are not intended in any way to limit the scope of the claims to the particular features having the corresponding reference numbers in the drawings.

1. A micrometer-scale torsion balance device (100) comprising:
a. a rigid mass (110); and
b. two or more nanoribbons (120) attached to the rigid mass (110);
wherein the rigid mass (110) is suspended by the two or more nanoribbons;
wherein the two or more nanoribbons (120) are placed under tensile stress; and
wherein a torsional stiffness of the two or more nanoribbons (120) is configured to allow derivation of a local acceleration value.

2. The device (100) of claim 1, wherein the rigid mass (110) comprises silicon.

3. The device (100) of claim 1, wherein the two or more nanoribbons (120) comprise silicon nitride.

4. The device (100) of claim 1, wherein a center of mass of the rigid mass (110) is offset from an axis of torsion of the two or more nanoribbons (120).

5. The device (100) of claim 1, wherein 100 or more megapascals of tensile stress are applied to the two or more nanoribbons (120).

6. The device (100) of claim 1, wherein the rigid mass (110) comprises a mirror surface, wherein a radiation pressure force can be derived from a movement of the rigid mass (110).

7. The device (100) of claim 1, wherein the rigid mass (110) is magnetic and comprises a mirror surface, wherein a strength and direction of a magnetic field is derived from a movement of the rigid mass (110).

8. The device (100) of claim 1 further comprising a resonator having a quality factor of 10,000 or more.

9. A micrometer-scale torsion balance device (100) comprising one or more nanoribbons (120), wherein the one or more nanoribbons (120) are placed under tensile stress, and wherein a local acceleration value is derived from a torsional stiffness of the one or more nanoribbons (120).

10. The device (100) of claim 9, wherein the two or more nanoribbons (120) comprise silicon nitride.

11. The device (100) of claim 9, wherein 100 or more megapascals of tensile stress are applied to the two or more nanoribbons (120).

12. The device (100) of claim 9, wherein the one or more nanoribbons (120) each comprise an optical waveguide, wherein amplitude and modulation of light directed through the optical waveguide can be derived from a torsional stiffness of the two or more nanoribbons (120).

13. The device (100) of claim 12 further comprising:
a. a light source optically coupled to the optical waveguide; and
b. a detection component optically coupled to the optical waveguide;
wherein the light source is configured to direct light through the optical waveguide;
wherein the detection component is configured to detect light directed through the optical waveguide by the light source.

14. A micrometer-scale torsion balance device (100) comprising:
a. a rigid mass (110); and
b. four or more nanoribbons (120) attached to the rigid mass (110), wherein the four or more nanoribbons (120) are in-plane with each other;
wherein a center of mass of the rigid mass (110) is offset from an axis of torsion of the four or more nanoribbons (120);
wherein the rigid mass (110) is suspended by the four or more nanoribbons (120);
wherein the four or more nanoribbons (120) are placed under tensile stress; and
wherein a torsional stiffness of the four or more nanoribbons (120) is configured to allow derivation of a local acceleration value.

15. The device (100) of claim 14, wherein the rigid mass (110) comprises silicon.

16. The device (100) of claim 14, wherein the four or more nanoribbons (120) comprise silicon nitride.

17. The device of claim 14, wherein 100 or more megapascals of tensile stress are applied to the four or more nanoribbons (120).

18. The device of claim 14, wherein the four or more nanoribbons (120) are parallel to each other.

19. The device of claim 14, wherein the rigid mass (110) comprises a mirror surface, wherein a radiation pressure force can be derived from a movement of the rigid mass (110).

20. The device of claim 14, wherein the rigid mass (110) is magnetic and comprises a mirror surface, wherein a strength and direction of a magnetic field is derived from a movement of the rigid mass (110).

21. (canceled)
